(19) United States
(12) Patent Application Publication
(10) Pub. No.: US 2016/0035730 A1
(43) Pub. Date: Feb. 4, 2016

(54) SEMICONDUCTOR DEVICE

(71) Applicant: PS4 Luxco S.a.r.l., Luxembourg (LU)

(72) Inventors: Mitsunari SUKEKAWA, Tokyo (JP); Takayuki MATSUI, Tokyo (JP)

(21) Appl. No.: 14/884,615

(22) Filed: Oct. 15, 2015

Related U.S. Application Data
(62) Division of application No. 13/778,267, filed on Feb. 27, 2013, now abandoned.

(30) Foreign Application Priority Data
Mar. 1, 2012 (JP) 2012-045237
Mar. 19, 2012 (JP) 2012-062256

(51) Int. Cl. H01L 27/108; H01L 49/02

(52) U.S. Cl. CPC H01L 27/10808; H01L 28/60

(57) ABSTRACT

A semiconductor device according to this invention includes a support film that supports a lower electrode of a capacitor at an upper portion, and the support film includes a first insulating material having a stress within a range of +700 MPa to −700 MPa. Use of such a support film prevents a phenomenon in which the capacitor lower electrode is twisted. Preferably, the support film has a rate etched by hydrofluoric acid of 1.0 nm/sec or less and more preferably, the support film includes a silicon carbon nitride film.

### CROSS-REFERENCES TO RELATED APPLICATIONS

This application is a divisional of, and claims priority to, U.S. patent application Ser. No. 13/778,267 entitled “Semiconductor Device,” filed on Feb. 27, 2013, which is hereby incorporated by reference.

### BACKGROUND OF THE INVENTION

1. Field of the Invention

The present invention relates to a semiconductor device.

2. Description of the Related Art

A semiconductor device including a memory element such as a DRAM (Dynamic Random Access Memory) retains electric charge in a capacitor. With the miniaturization of capacitors, it has become difficult for a conventional capacitor structure to achieve an electrode area for ensuring storage capacitance Cs required to retain electric charge. For this reason, a technique using an inner wall and an outer wall of a lower electrode (storage node electrode) of a closed-end cylinder type (with a crown structure) is proposed as a capacitor electrode structure. When lower electrodes are to be formed, holes (referred to as storage node holes) are formed in an insulating film (referred to as a mold insulating film) serving as a mold, and lower electrode conductors are formed. After that, the mold insulating film is removed to expose an inner wall and an outer wall of each lower electrode. Wet etching is mainly adopted to remove the mold insulating film. At the time of the etching, the following problems may occur. The lower electrodes may fall to cause a failure in subsequent capacitor film formation or the lower electrodes may contact each other to cause a short circuit failure. In order to prevent the problems, there are known techniques for forming a support film for electrode support at an upper portion of a lower electrode and a dielectric isolation structure (spacer structure) at a lower electrode upper portion (see JP2003-142605A, JP2003-297952A, JP2005-064504A, JP2005-150747A, and JP2005-229097A).

Note that a beam-shaped support film or a spacer structure disclosed in these documents may suffer from the problems of exfoliation at the time of wet etching of a mold insulating film, leaning of a lower electrode, and the like and is not sufficient, especially to support a cylindrical lower electrode having a small diameter. For this reason, attempts have been made to reduce openings to be formed in a support film and increase the area of contact between a lower electrode and the support film.

However, if a support film having such a large area is used for an electrode having a thickness of about 10 nm or less as a result of further miniaturization, the support film at an upper portion of the electrode causes a phenomenon in which the electrode is twisted. This leads to a problem of yield reduction resulting from, e.g., a failure in formation of a capacitor dielectric film.

A process of preventing an electrode twist by increasing the thickness of a support film is conceivable. The process reduces the area of an outer wall to serve as a capacitive portion of a lower electrode by an amount corresponding to the increase in thickness. Additionally, the selectivity of a silicon nitride film used as the support film to a mask at the time of dry etching is low, and the increase in the film thickness makes formation of a storage node hole having a high aspect ratio difficult. There is thus a limit to the film thickness of a support structure.

JP2006-135261A proposes a method of manufacturing a cylindrical capacitor using an amorphous carbon film (hereinafter referred to as an AC film) as a mold insulating film instead of a silicon oxide film. In this document, the AC film is removed by dry etching using an etching gas mainly composed of oxygen (O₂). The method performs etching mainly by radical reactions and can thus advance etching, regardless of attenuation of the kinetic energy of ions. Additionally, a hole pattern having a high aspect ratio can be formed with high accuracy by reducing occurrence of bowing due to radical reactions using an additive gas. JP2012-231075A proposes a structure in which an opening having a high aspect ratio is formed using an AC film and a lower electrode of a cylindrical capacitor is two-dimensionally supported by a support film made of a silicon nitride film. Even the method, however, does not solve the problem of a lower electrode twist resulting from a support film.

### SUMMARY OF THE INVENTION

According to one aspect of the present invention, there is provided a semiconductor device including a capacitor; and a support film that supports the capacitor, the support film comprising a first insulating material having a stress within a range of +700 MPa to −700 MPa. The first insulating material is a material which has an etch rate relative to hydrofluoric acid of not more than 1 nm/sec. More specifically, the first insulating material is preferably a silicon carbon nitride (SiCN) film.

According to another aspect of the present invention, there is provided a semiconductor device including a capacitor; and at least two support films separately supporting the capacitor in a height direction thereof and the at least two support films comprising silicon nitride doped with carbon.

According to still another aspect of the present invention, there is provided a semiconductor device including a transistor formed on a semiconductor substrate; a capacitor comprising a cylindrical lower electrode electrically connected to one of source/drain diffusion layers of the transistor; and a support structure being in contact with an outer wall of the cylindrical lower electrode at a portion higher than the middle height of the cylindrical lower electrode, the support structure comprising a silicon carbon nitride film.

According to any one of aspects of the present invention, since the support film is a small stress within a specific range, especially a silicon carbon nitride (SiCN) film, a cylinder twist due to global stress between the support film, a lower electrode, a capacitor dielectric film, and an upper electrode can be prevented.

According to any one of aspects of the present invention, reduction in an outer-wall area of a lower electrode used as a capacitive portion can be suppressed, in addition to prevention of a cylinder twist.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a plan view showing memory cell region 10 and peripheral circuit region 12 of a DRAM according to one embodiment of the present invention after a mold insulating film is removed, and FIG. 1B is a cross-sectional view in FIG. 1A;

FIG. 2A is a plan view for explaining a problem to be solved by the present invention;

FIG. 2B is a cross-sectional view taken along line A-A in FIG. 2A;

FIG. 2C is a view showing a result of observing the state of twists in the semiconductor device shown FIGS. 2A and 2B by a scanning electron microscope (SEM);

FIG. 3 is a chart showing the relationship between HF etch rates and stress of each of various materials;

FIG. 4A is a plan view for explaining one step of manufacturing a semiconductor device according to the one embodiment of the present invention, and FIG. 4B is a cross-sectional view taken along line B-B in FIG. 4A;

FIG. 5A is a plan view for explaining a step to be performed after the step shown in FIG. 4A, and FIG. 5B is a cross-sectional view taken along line B-B in FIG. 5A;

FIG. 6A is a plan view for explaining a step to be performed after the step shown in FIG. 5A, and FIG. 6B is a cross-sectional view taken along line B-B in FIG. 6A;

FIG. 7A is a plan view for explaining a step to be performed after the step shown in FIG. 6A, and FIG. 7B is a cross-sectional view taken along line B-B in FIG. 7A;

FIG. 8A is a plan view for explaining a step to be performed after the step shown in FIG. 7A, and FIG. 8B is a cross-sectional view taken along line B-B in FIG. 8A;

FIG. 9A is a plan view showing memory cell region 10 and peripheral circuit region 12 of a DRAM obtained according to the one embodiment of the present invention, and FIG. 9B is a cross-sectional view taken along line B-B in FIG. 9A;

FIGS. 10A, 10B, and 10C are views showing results of comparing, using respective SEM observation images, the state of twists across a memory mat when ALD-SiN according to a comparative example is used for a support film, the state of twists across a memory mat when P—SiCN according to the present invention is used for a support film, and the state of twists across a memory mat when HDP—SiN according to a comparative example is used for a support film;

FIG. 11 is a chart showing a result of examining the correlation between the magnitude of stress and the number of defective bits in a DRAM chip for each of DRAMs including support films made of various materials;

FIGS. 12A and 12B show a vertical cross-sectional view and a plan view for explaining a process of manufacturing a semiconductor device according to another embodiment of the present invention, and FIG. 12A is a cross-section along A-A′ in FIG. 12B;

FIGS. 13A and 13B show vertical and horizontal cross-sectional views for explaining the process of manufacturing a semiconductor device according to the other embodiment of the present invention, FIG. 13A is a cross-section along A-A′ in FIG. 13B, and FIG. 13B is a cross-section along B-B′ in FIG. 13A;

FIGS. 14A and 14B show a vertical cross-sectional view and a plan view for explaining the process of manufacturing a semiconductor device according to the other embodiment of the present invention, and FIG. 14A is a cross-section along A-A′ in FIG. 14B;

FIGS. 15A and 15B show a vertical cross-sectional view and a plan view for explaining the process of manufacturing a semiconductor device according to the other embodiment of the present invention, and FIG. 15A is a cross-section along A-A′ in FIG. 15B;

FIGS. 16A and 16B show a vertical cross-sectional view and a plan view for explaining the process of manufacturing a semiconductor device according to the other embodiment of the present invention, and FIG. 16A is a cross-section along A-A′ in FIG. 16B;

FIGS. 17A and 17B show a vertical cross-sectional view and a plan view for explaining the process of manufacturing a semiconductor device according to the other embodiment of the present invention, and FIG. 17A is a cross-section along A-A′ in FIG. 17B;

FIGS. 18A and 18B show a vertical cross-sectional view and a plan view for explaining the process of manufacturing a semiconductor device according to the other embodiment of the present invention, and FIG. 18A is a cross-section along A-A′ in FIG. 18B;

FIG. 19 is a chart showing the relationships between a carbon-doped amount in a silicon nitride film (the flow rate of trimethylsilane) and etch rates (wet and dry); and

FIGS. 20 and 21 show vertical cross-sectional views for explaining a manufacturing process of a semiconductor device according to still another embodiment of the present invention.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purpose.

### First Embodiment

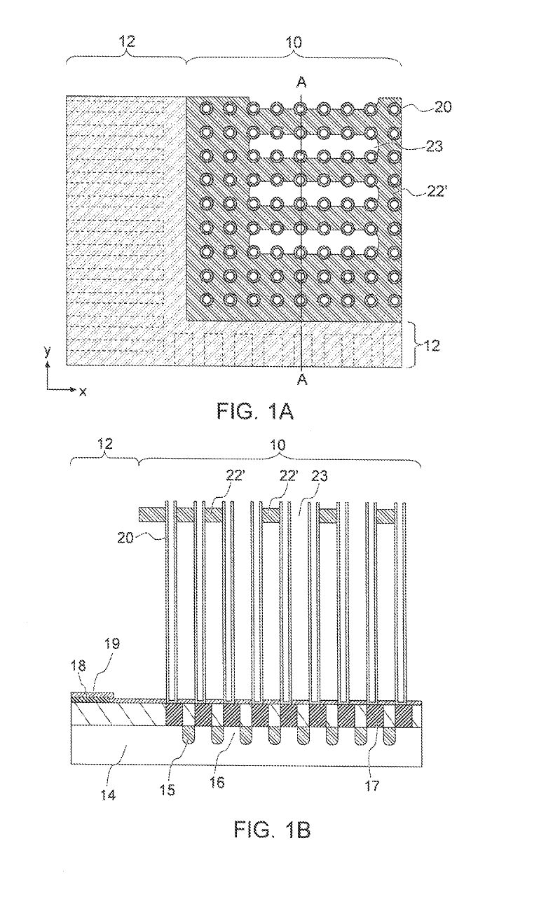

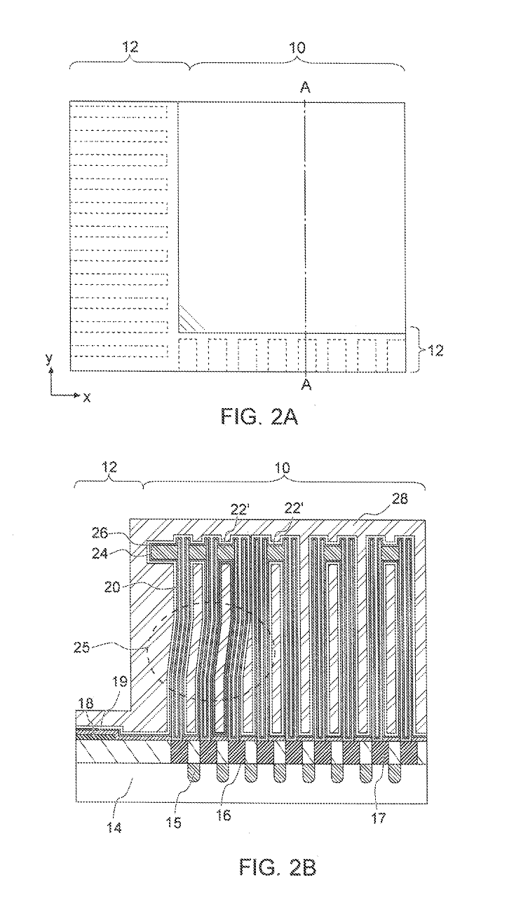

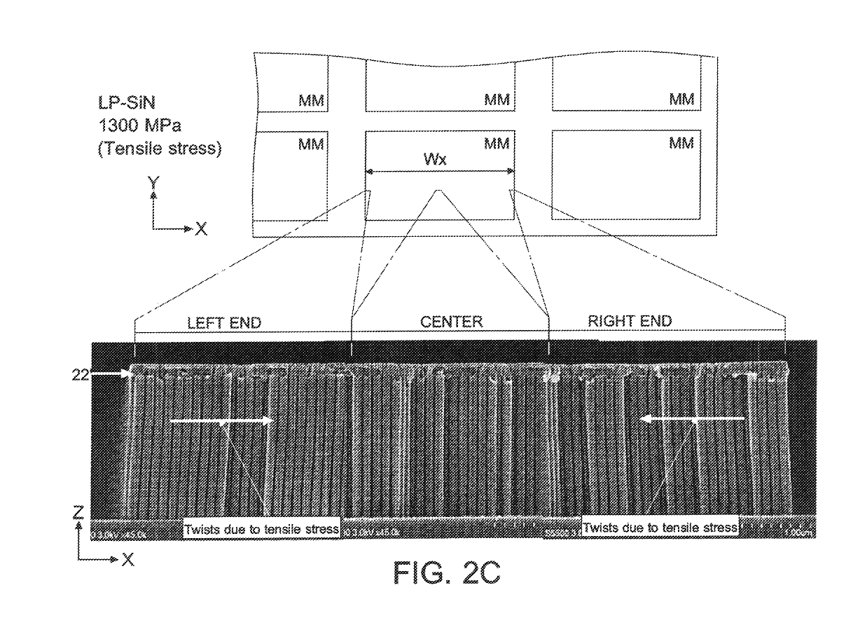

For ease of understanding of the present invention, a cylinder twist phenomenon, which may occur in a cylindrical capacitor, will first be described with reference to FIGS. 1A, 1B, 2A, and 2B. Although a semiconductor device including a cylindrical capacitor will be described in the context of a DRAM, the present invention is not limited to a DRAM.

FIG. 1A is a plan view showing memory cell region 10 and peripheral circuit region 12 of a DRAM after a mold insulating film is removed. FIG. 1B is a cross-sectional view taken along line A-A in FIG. 1A. FIGS. 1A and 1B show a state in which lower electrodes of cylindrical capacitors are formed in memory cell region 10. More specifically, as shown in FIG. 1B, active regions 16 demarcated by STIs 15 are provided in substrate (e.g., a silicon substrate) 14. Although only capacitor contact plug 17 is provided in active region 16 in FIG. 1B for illustrative simplicity, a transistor including diffusion regions and a gate region are actually provided in substrate 14, and capacitor contact plug 17 is electrically connected to one of the diffusion regions.

In peripheral circuit region 12, peripheral circuit wiring 18 and the like are provided. Peripheral circuit wiring 18 is covered with silicon nitride film 19. Silicon nitride film 19 in memory cell region 10 is selectively etched such that surfaces of capacitor contact plugs 17 are exposed.

Lower electrode 20 of a cylindrical capacitor is formed so as to be electrically connected to capacitor contact plug 17. An upper portion of lower electrode 20 is supported by support film 22′ that is made of, e.g., a silicon nitride film. Lower electrode 20 is made of, e.g., TiN, and a cylindrical hole is defined inside lower electrode 20. Support film 22′ shown in FIG. 1B has opening 23 that extends in a lateral direction (x-direction) in FIG. 1A. As shown in FIG. 1B, among cylindrical lower electrodes 20 arranged in y-direction, ones exposed in opening 23 are supported by support film 22′ only from one side in the y-direction. The height of lower electrode 20 is appropriately set according to electrostatic capacitance Cs as required. For example, the ratio of the height to the outer diameter (height/outer diameter: aspect ratio) of each lower electrode is preferably not less than 20, more preferably not less than 30.

FIGS. 2A and 2B are a plan view and a cross-sectional view, respectively, showing a state after cylindrical capacitors are formed. That is, referring to FIG. 2B, a state is shown in which, after lower electrodes 20 and support film 22′ are provided, as shown in FIG. 1B, capacitor dielectric film 24 is formed on outer and inner walls of lower electrodes 20, upper electrode 26 such as TiN film is provided on capacitor dielectric film 24, and each combination of lower electrode 20, capacitor dielectric film 24, and upper electrode 26 constitutes a capacitor. Capacitor dielectric film 24 and upper electrode 26 are also present on support film 22′ and silicon nitride film 19. The cylindrical capacitors shown in FIG. 2B are all covered with a gap filling material 28 such as a doped polysilicon film and a boron doped silicon germanium (B-doped SiGe) film. In a semiconductor device including cylindrical capacitors manufactured in the above-described manner, a phenomenon in which cylinder twists 25 occurred was observed at upper portions of ones close to peripheral circuit region 12 among the cylindrical capacitors in memory cell region 10, as shown in FIG. 2B.

FIG. 2C shows a result of observing the state of twists across a memory mat (MM) by a scanning electron microscope (SEM). A semiconductor chip as a product is composed of multiple memory mats each having multiple memory cells (bits). A semiconductor chip in which memory mats each have 1068 capacitors aligned in an X direction and manufactured capacitors were capacitors as described above was used here as an observation sample. Width Wx in the X direction of one memory mat is about 100 μm. As a support film, a silicon nitride film (LP—SiN) which was formed by low-pressure CVD using dichlorosilane (SiH₂Cl₂) and ammonia (NH₃) as source gases under the conditions of temperature of 750° C. and pressure of 0.5 Torr was used. LP—SiN has a stress (tensile stress) of +1300 MPa.

FIG. 2C shows a combination of SEM images that are obtained by observing a left end portion, a central portion, and a right end portion in the X direction as three typical spots of one memory mat. In the combined SEM image, a rod-like portion extending upward from a semiconductor substrate corresponds to one capacitor. As can be seen from the SEM image, capacitors located at the left end and right end portions are affected by tensile stress (acting in a direction in which support film 22 contracts) of the film and lean toward the central portion. That is, the capacitors located at the left end and right end portions are twisted. In the central portion, individual capacitors stand together perpendicularly to an upper surface of the semiconductor substrate and are in normal condition. In contrast, although the capacitors located at the left end portion are fixed at lower ends in contact with the base substrate, since there is no support structure other than the support film at upper ends, the capacitors lean toward the central portion while being drawn in a direction of an arrow when the support film contracts. The capacitors located at the right end portion are placed in a similar state. The leaning occurs when a mold insulating is removed after storage node holes are formed in a layered film of the mold insulating film and the support film, and respective lower electrodes are formed in the storage node holes. The lower electrodes having been perpendicular at the time of formation are forcibly bent in a subsequent step. For this reason, various defects responsible for defective bits, such as breakage of a lower electrode itself, are produced in lower electrodes in a region with leaning, in addition to cylinder clogging as shown in FIG. 2B. The present invention provides a semiconductor device which reduces global stress across a memory mat and reduces occurrence of defective bits which occur frequently especially in a marginal region of a memory mat.

As a result of pursuing the cause of cylinder twist 25 on the basis of the SEM observation result, the present inventors have found out that cylinder twist 25 is due to imbalance in stress between lower electrodes 20, capacitor dielectric film 24, upper electrode 26, gap filling material 28, and support film 22′, especially between support film 22′ and the other films.

A silicon nitride film (ALD-SiN) that is formed by ALD (Atomic Layer Deposition) also has a large stress, i.e., +1200 MPa (tensile stress). It was found that if support film 22′ had such a large tensile stress, cylinder twist 25 as shown in FIG. 2B occurred.

For this reason, the present inventors tried various materials for support film 22′. A silicon nitride film (P—SiN) formed by plasma CVD, a silicon oxide film (P—SiO₂) formed by plasma CVD, a silicon nitride film (HDP—SiN) formed by high-density plasma CVD, and a silicon carbon nitride film (P—SiCN) formed by plasma CVD were contemplated as materials used for support film 22′. Support film 22′ not only needs to balance with the other films simply in terms of stress but also needs to have high etch resistance to, i.e., a low etch rate relative to hydrofluoric acid. This is because wet etching is performed using hydrofluoric acid to remove a mold insulating film that is mainly a silicon oxide film when cylindrical lower electrode 20 is formed, and support film 22′ needs to be prevented from being removed together with the mold insulating film at the time of the wet etching. That is, support film 22′ needs to have a low etch rate relative to hydrofluoric acid.

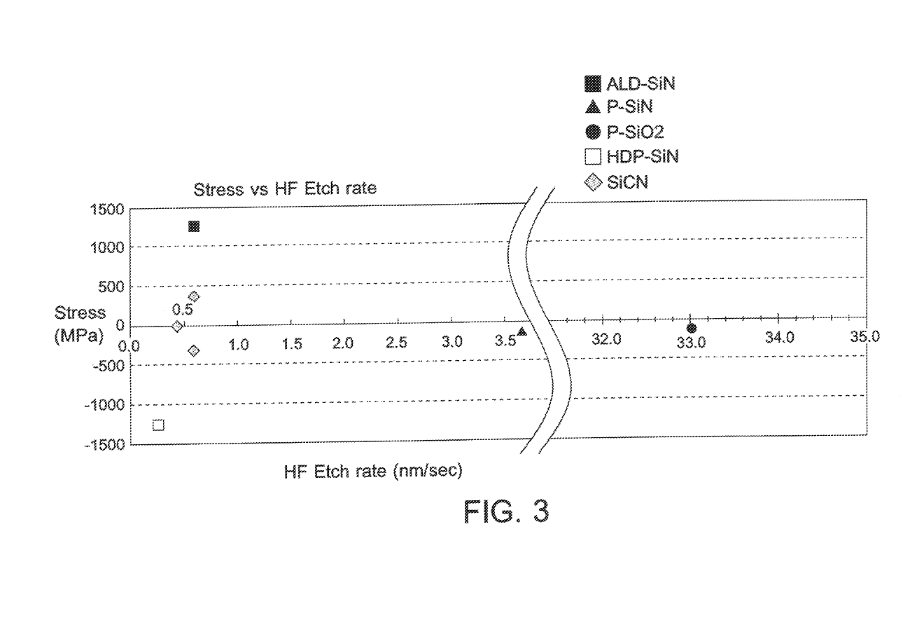

Referring to FIG. 3, the relationships between the etch rates relative to hydrofluoric acid (hereinafter referred to HF etch rates) and stress (tensile stress or compressive stress) of P—SiN, P—SiO₂, HDP—SiN, and P—SiCN are shown together with the case of ALD-SiN. The axis of ordinate in FIG. 3 represents stress (MPa), tensile stress on the positive side and compressive stress on the negative side. The axis of abscissa in FIG. 3 represents HF etch rate (nm/sec).

As can be seen from FIG. 3, ALD-SiN has an HF etch rate (0.6 nm/sec) lower than 1 nm/sec but has a large stress (tensile stress) of about +1200 MPa. HDP—SiN has a low HF etch rate but has a large stress (compressive stress) of about −1200 MPa. Although P—SiN and P—SiO₂ have small stresses, they have high HF etch rates and are unsuitable for a support film.

In contrast, P—SiCN has a stress of about ±300 MPa and an HF etch rate (about 0.5 nm/sec in FIG. 3) lower than 1 nm/sec and is found to be suitable for a support film. Note that an HF etch rate is an etch rate relative to a commercially available hydrofluoric acid (an aqueous HF solution having a concentration of 47 to 48%).

Based on the above experimental results, the present invention uses a P—SiCN film as a support film.

The embodiment of the present invention will be described below in order of processes.

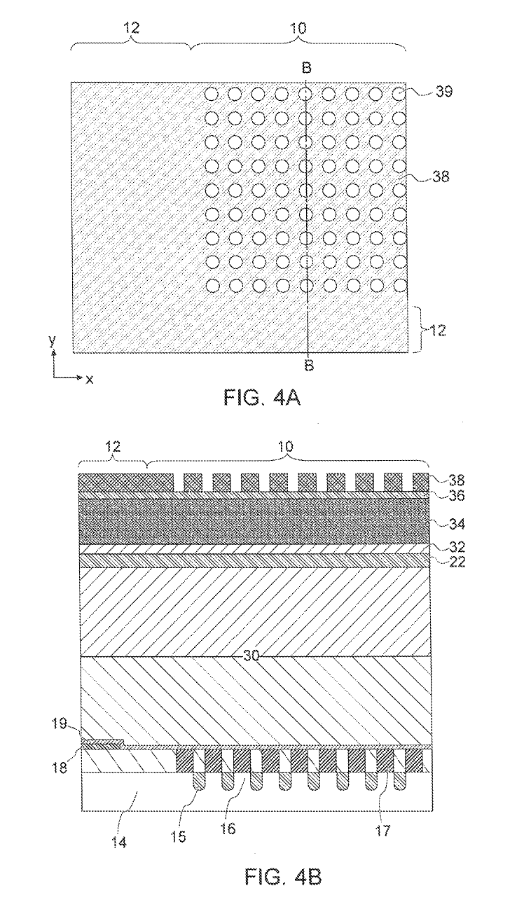

FIG. 4A is a plan view of memory cell region 10 and peripheral circuit region 12, and FIG. 4B is a cross-sectional view taken long line B-B in FIG. 4A.

As shown in FIG. 4B, capacitor contact plugs 17 are formed in interlayer insulating film in memory cell region 10 demarcated by STIs 15 in substrate 14, and peripheral circuit wiring 18 is formed in peripheral circuit region 12. Capacitor contact plugs 17 and peripheral circuit wiring 18 are covered with nitride film 19 serving as an etch stopper at the time of dry etching to be performed at the time of storage node hole formation. Nitride film 19 also functions as a protective film which blocks the underlying interlayer insulating film from being etched when mold insulating film 30 is removed in a subsequent step. In the example shown in FIG. 4B, mold insulating film 30 is provided on nitride film 19. Although mold insulating film 30 is provided as two layers, the two layers are collectively referred to as mold insulating film 30 here for explanative simplicity. Examples of two-layered mold insulating film 30 include a film in which a P—SiO₂ film having a low dry etch rate is stacked on a BPSG film having a high dry etch rate. With the use of the layered structure, a failure in formation of a storage node hole having a high aspect ratio and a phenomenon called bowing in which a storage node hole bulges outward at an upper portion can be reduced. Mold insulating film 30 is not limited to a two-layered film and can be a single-layered film or a layered film with three or more layers. A film to be used as mold insulating film 30 can be appropriately selected according to the aspect ratio of a capacitor to be formed.

Further referring to FIG. 4B, support film 22 is provided on mold insulating film 30. Support film 22 shown in FIG. 4B is made of P—SiCN, which is based on the measurement result shown in FIG. 3. Silicon oxide film 32 is formed on support film 22, and amorphous carbon film (α-C) 34 and surface silicon oxide film 36 are sequentially formed on silicon oxide film 32. Surface silicon oxide film 36 shown in FIG. 4B is coated with patterned resist film 38. Amorphous carbon film 34 and resist film 38 are provided to form storage node holes for capacitors.

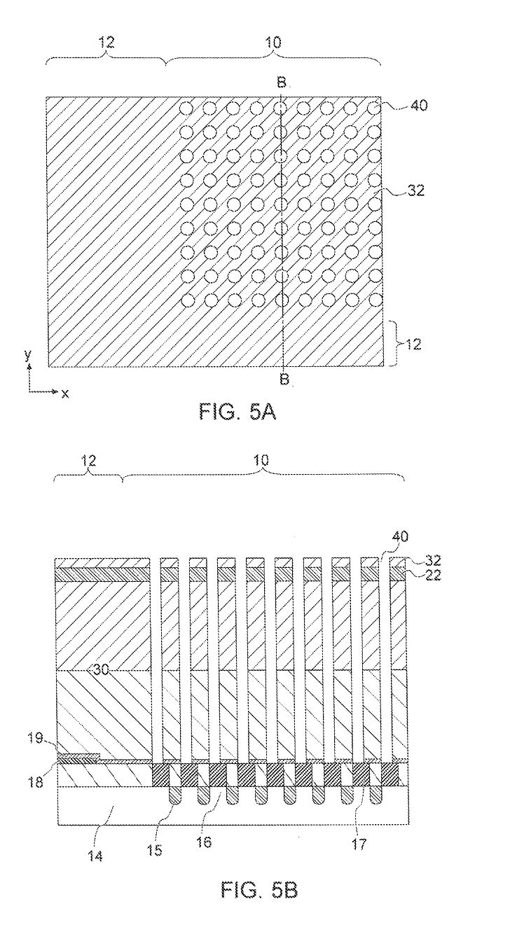

FIGS. 5A and 5B show a state in which storage node holes 40 extending from silicon oxide film 32 to reach capacitor contact plugs 17 are formed by dry etching using resist film 38 as a mask. FIG. 5B is a cross-sectional view taken along line B-B in FIG. 5A and shows a state in which resist film 38, surface silicon oxide film 36, and amorphous carbon film 34 shown in FIG. 4B are removed. Storage node holes 40 shown in FIGS. 5A and 5B extend from silicon oxide film 32 through support film 22 made of P—SiCN, mold insulating film 30, and silicon nitride film 19 to reach capacitor contact plugs 17.

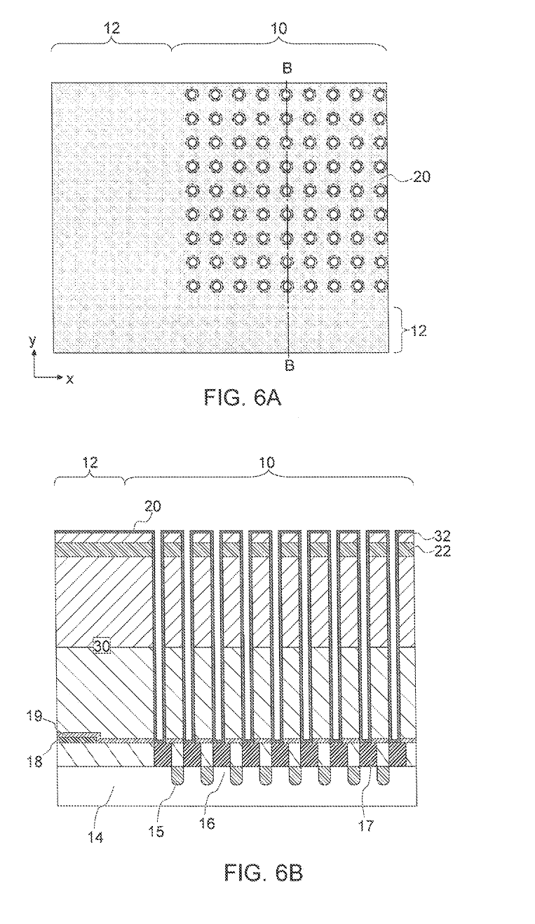

FIGS. 6A and 6B are a plan view and a cross-sectional view, respectively, showing a step to be performed after the step shown in FIG. 5B. A metal film (a titanium nitride film: TiN) to form lower electrodes 20 is formed on inner walls of storage node holes 40 and on a surface of silicon oxide film 32. The TiN film to form lower electrodes 20 covers the inner walls of storage node holes 40 and reaches capacitor contact plugs 17 to form inner wall films of storage node holes 40.

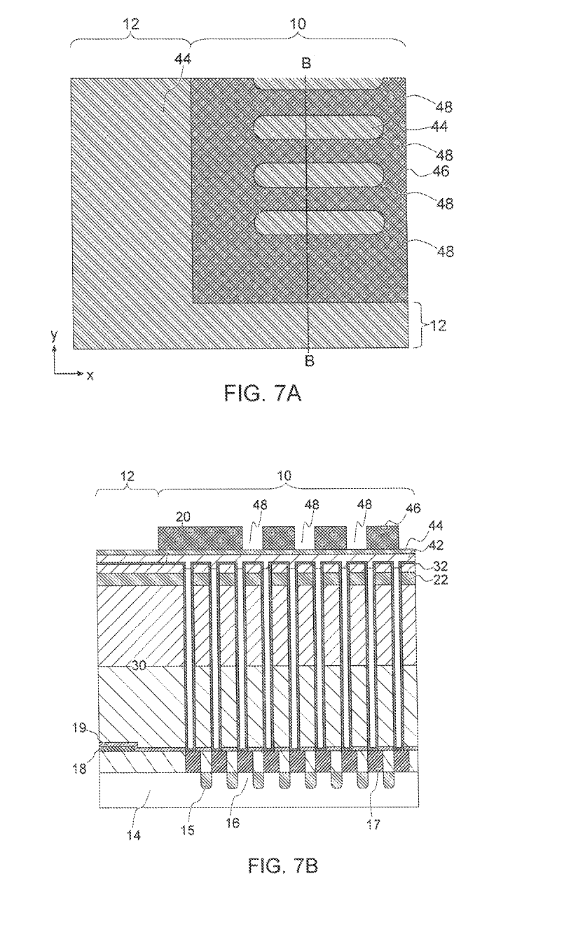

FIGS. 7A and 7B are a plan view and a cross-sectional view, respectively, showing a step to be performed after the step shown in FIG. 6B. Plasma silicon nitride film (P—SiN film) 42 is formed so as to cover the TiN film for lower electrode 20 formed at the inner walls of storage node holes 40 and on the surface of silicon oxide film 32, and silicon oxide film 44 is formed on P—SiN film 42. Silicon oxide film 44 is further coated with patterned resist 46. P—SiN film 42 has a function as a cap film that prevents the resist from entering into inner wall surfaces of lower electrode 20 at the time of photolithography for forming openings 23 in support film 22. As can be seen from FIG. 7B, resist 46 is patterned for forming opening patterns 48 corresponding to openings 23 to be formed in support film 22.

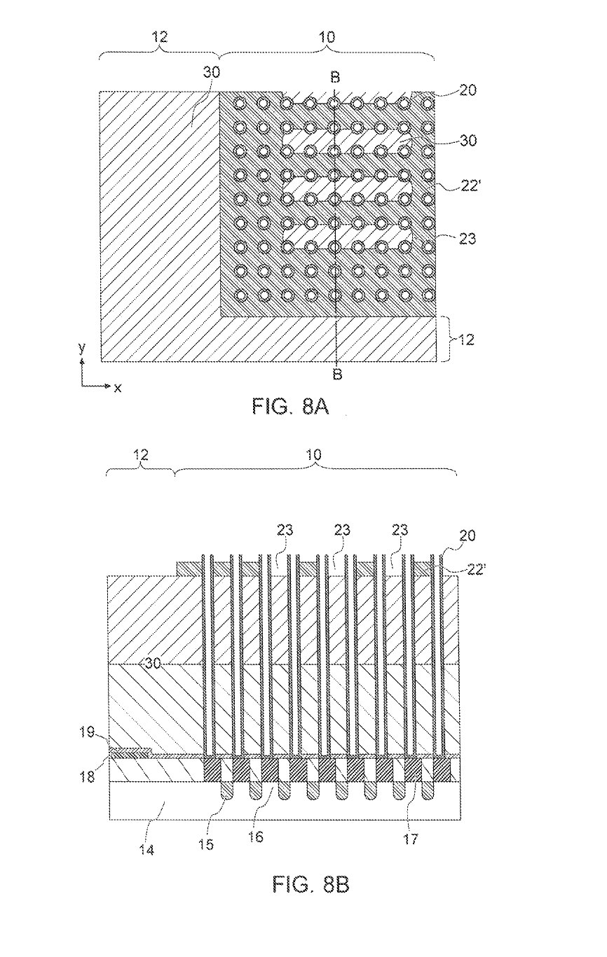

Referring to FIGS. 8A and 8B, the SiCN film forming support film 22 is etched by dry etching to form openings 23. The support film after openings 23 are formed is referred to as support film 22′.

Mold insulating film 30 is removed via openings 23 in support film 22′. Mold insulating film 30 is removed by wet etching using hydrofluoric acid as an etching chemical solution. With this process, mold insulating film 30 in memory cell region 10 is removed, and the same state as in FIGS. 1A and 1B is obtained.

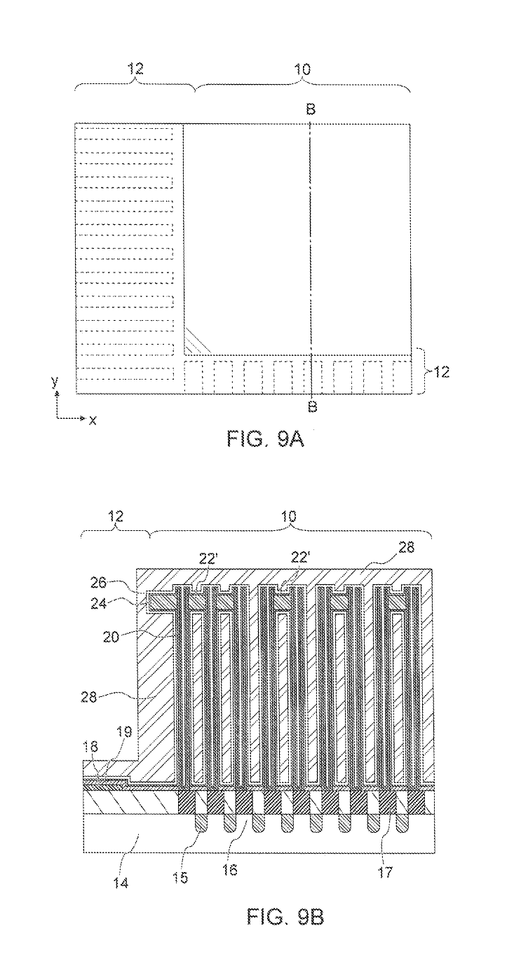

After the same state as in FIGS. 1A and 1B is obtained, capacitor dielectric film 24 and upper electrode 26 are formed on lower electrodes 20, as shown in FIGS. 9A and 9B, thereby forming cylindrical capacitors. This embodiment uses TiN films as lower electrode 20 and upper electrode 26 and uses a high dielectric constant film of, e.g., zirconium oxide (ZrO₂), aluminum oxide (Al₂O₃), or hafnium oxide (HfO₂) as capacitor dielectric film 24. After that, gap-filling material 28 such as B-dope SiGe is formed, and a semiconductor device is completed.

When SiCN (a silicon carbon nitride film) having a small stress and a low HF etch rate was used as support film 22, as described above, cylinder twist 25 as shown in FIG. 2B could be prevented from occurring, and the yield of cylindrical capacitors could be significantly increased.

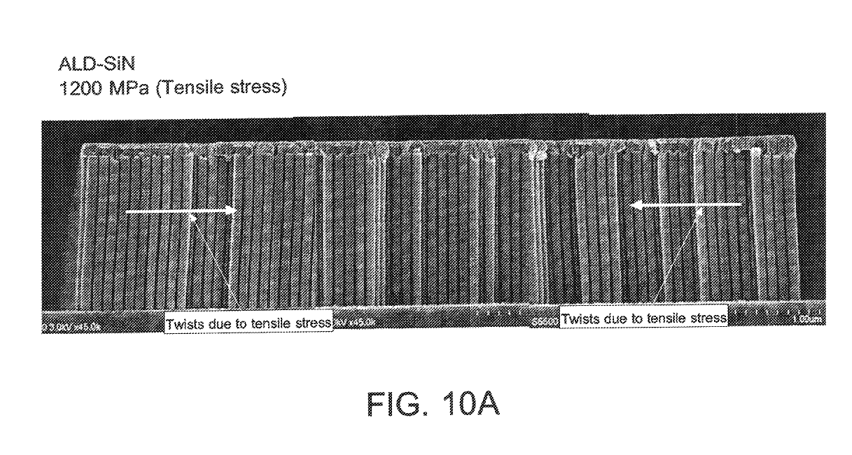

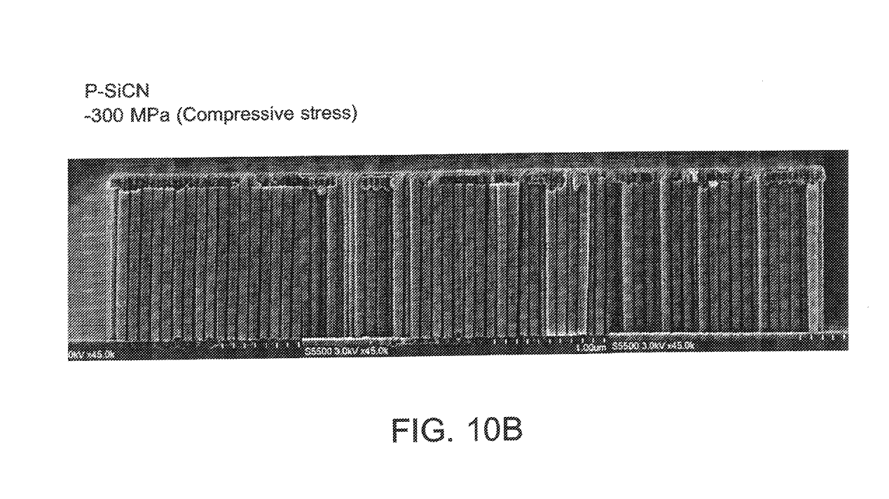

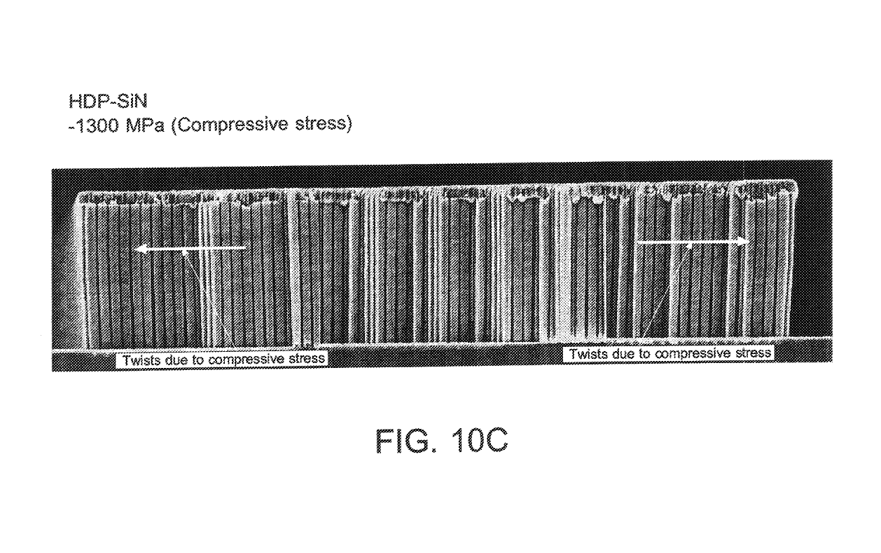

FIGS. 10A, 10B, and 100 show results of comparing, using respective SEM observation images, the state of twists across a memory mat when ALD-SiN according to a first comparative example is used for a support film, the state of twists across a memory mat when P—SiCN according to the present invention is used for a support film, and the state of twists across a memory mat when HDP—SiN according to a second comparative example is used for a support film. ALD-SiN has a stress (a tensile stress like LP—SiN described above) of +1200 MPa, P—SiCN has a stress (compressive stress) of −300 MPa, and HDP—SiN has a stress (compressive stress) of −1300 MPa. Observation samples for the SEM images were fabricated in the same manner as in FIG. 2C. As can be seen from FIGS. 10A to 10C, in the case of ALD-SiN shown as the first comparative example, capacitors at left and right end portions has been twisted toward a central region due to tensile stress, like the case of LP—SiN described above. In the case of HDP—SiN shown as the second comparative example, capacitors at left and right end portions has been twisted from a central portion toward the respective end portions due to compressive stress. In contrast, in the case of P—SiCN according to the present invention, capacitor twist is not observed across the memory mat. This indicates that use of a small-stress film as a support film reduces global stress across a memory mat and prevents capacitors located in a marginal region from leaning.

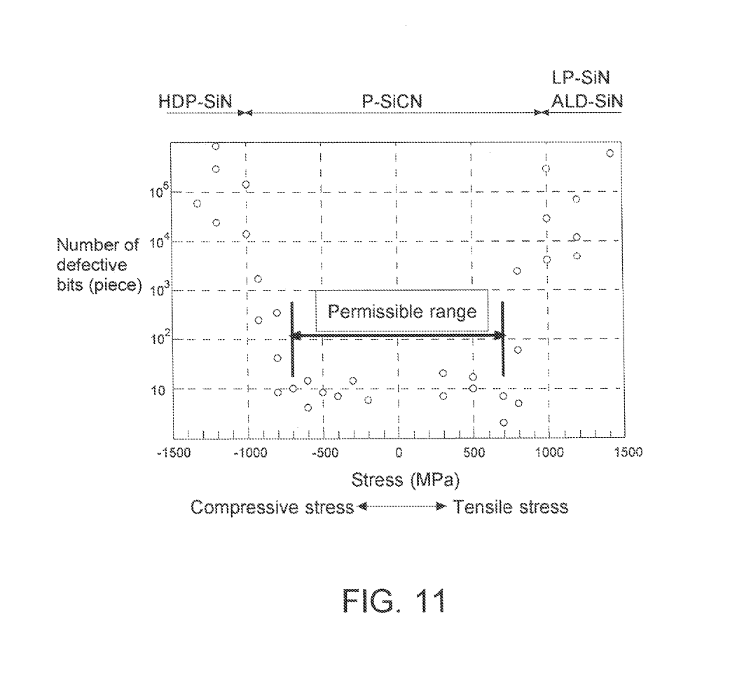

FIG. 11 is a result of examining the correlation between the magnitude of stress and the number of defective bits in a DRAM chip for each of DRAMs including support films made of the above-described materials having various stresses. The result shows that the number of defective bits can be kept within a permissible range up to 30 pieces by adjusting stress using a P—SiCN film having a stress within a range of +700 MPa to −700 MPa. The stress of the P—SiCN film can be controlled by adjusting plasma power and the ratio between the flow rates of mono-silane (SiH₄) gas and trimethylsilane (Si(CH₃)₃) gas used as source gases. This means adjusting the amount of carbon (C), with which silicon nitride (SiN) is doped. Stoichiometric silicon carbon nitride is Si_{1.5}C_{1.5}N₄. In the present invention, both of stoichiometric and nonstoichiometric silicon carbon nitrides can be used if they satisfy conditions required for the support film.

An experiment of the present inventors showed that use of SiCN having a small stress of about −300 MPa as support film 22′ was desirable in terms of preventing cylinder twist 25 resulting from support film 22′.

The experiment also showed that the direction of a cylinder twist changed depending on the direction of the stress of support film 22′. In other words, a cylinder twist can be controlled by controlling the stress of support film 22′.

If the mold insulating film is removed by HF wet etching, a film having a low HF etch rate, especially an HF etch rate of not more than 1.0 nm/sec, is desirably used as support film 22′.

P—SiCN film used in the present embodiment is a desirable material in that it satisfies the criterion of low HF etch rate, as shown in FIG. 3.

An ALD-SiN film and an HDP—SiN film have low HF etch rates not more than 1.0 nm/sec, as shown in FIG. 3. There is a possibility to reduce the capacitor twist 25 by stacking and combining these films and adjusting the stress to a range of +700 MPa to −700 MPa.

If an AC film is used as the mold insulating film, the need to take an HF etch rate into consideration is eliminated. A film of P—SiN or P—SiO₂ having a small stress within a range of +700 MPa to −700 MPa can also be used as the support film.

The preferred embodiment of the present invention has been described above. The present invention, however, is not limited to the above embodiment, and various changes can be made without departing from the spirit of the present invention. Such changes are, of course, included within the scope of the present invention. For example, although the above embodiment has illustrated an example in which one support film is formed at upper portions of lower electrodes, the present invention is not limited to this, and two or more support films may be formed.

### Second Embodiment

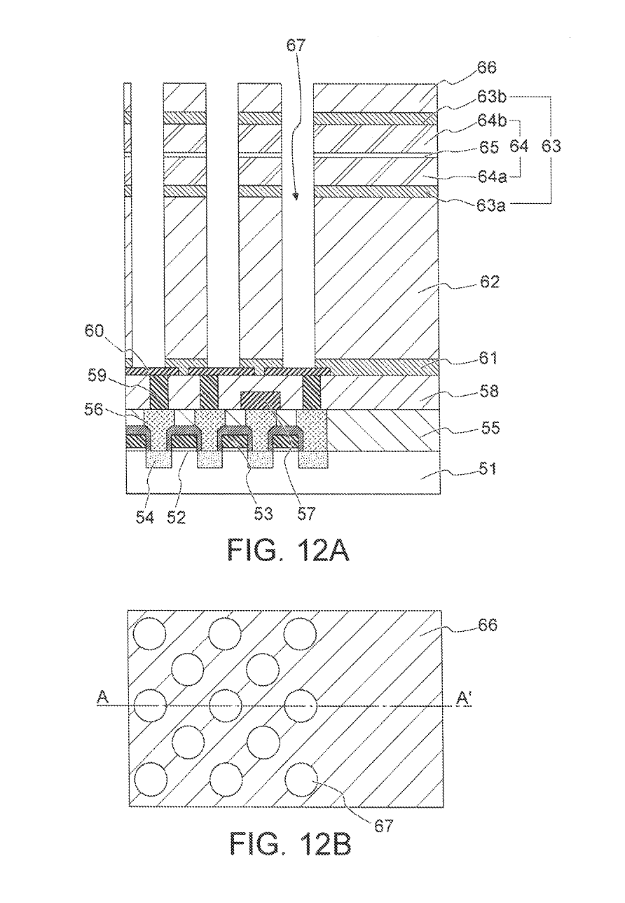

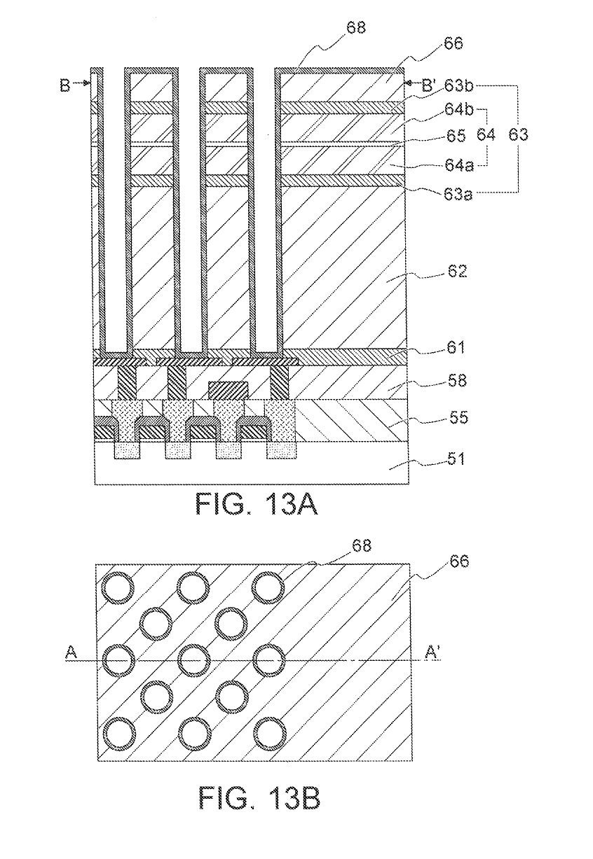

A manufacturing process of a semiconductor device according to the present embodiment will be described with reference to FIGS. 12A to 18B. Of FIGS. 12A to 18B, FIGS. 12A, 13A, 14A, 15A, 16A, 17A, and 18A show cross-sectional views along line A-A′ in FIGS. 12B, 13B, 14B, 15B, 16B, 17B, and 18B, respectively, and FIGS. 12B, 14B, 15B, 16B, 17B, and 18B show plan views (only FIG. 13B shows a cross-sectional view along B-B′ in FIG. 13A).

Referring to FIGS. 12A and 12B, semiconductor elements (e.g., transistors) each including gate insulating film 52 and gate electrode 53 are formed on semiconductor substrate 51 demarcated by element isolation regions (not shown), according to conventional procedures. One of source/drains 54 of each transistor is connected to capacitor contact pad 60 via substrate contact plug 56 and capacitor contact plug 59 while the other is connected to bit line 57 via substrate contact plug 56. Reference numerals 55 and 58 denote interlayer insulating films.

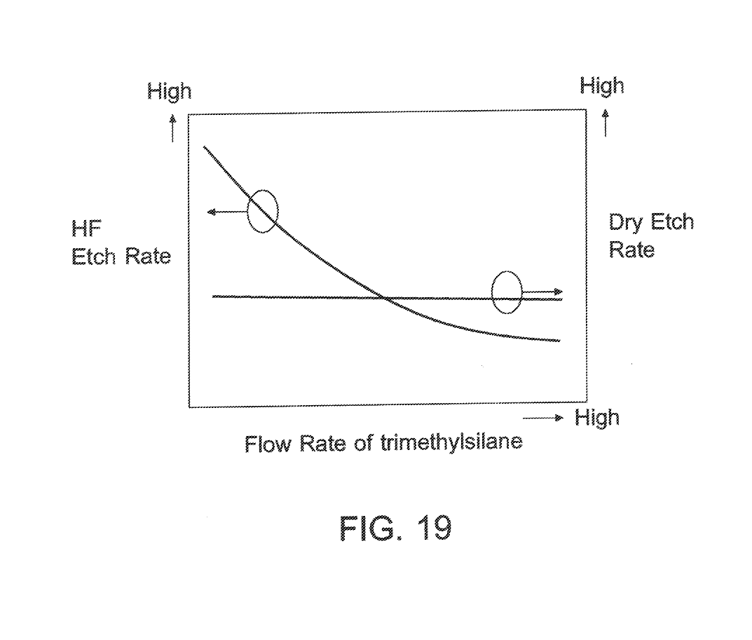

Stopper film 61 with 50 nm-thick and mold insulating film 62 with 1,000 nm-thick are formed on capacitor contact pad 60 by CVD. Stopper film 61 is made of a first silicon nitride film and mold insulating film 62 is made of a silicon oxide film. On mold insulating film 62, first insulating film 63a with 50 nm-thick, second insulating film 64a with 80 nm-thick, third insulating film 65 with 20 nm-thick as, fourth insulating film 64b with 100 nm-thick, and fifth insulating film 63b with 50 nm-thick are formed. Here, first and fourth insulating films (63a and 63b) are made of first silicon nitride film 63 and second and fifth insulating films are made of second silicon nitride film 64. Sixth insulating film 66 with 100 nm-thick is further formed on fifth insulating film 63b. Third and sixth insulating films (65 and 66) are made of a silicon oxide film. A storage node hole pattern (not shown) having a hole diameter of 40 nm is formed by lithography, and storage node holes 67 are made using the storage node hole pattern as a mask. The first silicon nitride films (61, 63a, and 63b) and the second silicon nitride films (64a and 64b) are formed by plasma CVD using a gas mixture of silane (SiH₄), ammonia (NH₃), and trimethylsilane ((CH₃)₃SiH). Silicon nitride films having different wet etch rates relative to hydrofluoric acid (HF) can be formed by adjusting the ratio of the flow rate of trimethylsilane, as shown in FIG. 19. The silicon nitride films have substantially the same dry etch rates, regardless of their ratios of the flow rate of trimethylsilane. In FIGS. 12A and 12B, a film having a low wet etch rate is used as the first silicon nitride film, and a film having a high wet etch rate is used as the second silicon nitride film. The wet etch rate of the first silicon nitride film is preferably not more than three-quarters of the wet etch rate of the second silicon nitride film, more preferably not more than one-half, most preferably not more than one-fifth. Note that the second silicon nitride film has a wet etch rate sufficiently lower than that of the silicon oxide film and that, as will be described later, a part of each second silicon nitride films is left after the silicon oxide films are all removed in a wet etching step. The first silicon nitride film is formed as an insulating film (a silicon carbon nitride film) obtained by doping silicon nitride with carbon, and the second silicon nitride film is formed as a silicon nitride film (a silicon carbon nitride film) more lightly doped with carbon than the first silicon nitride film or a silicon nitride film undoped with carbon. For example, the first silicon nitride film can be a P—SiCN film having a stress within a range of ±700 MPa as used in the first embodiment and the second silicon nitride film can be a P—SiN film shown in FIG. 3. The first silicon nitride films and second silicon nitride films are formed not only by plasma CVD using the above-described source gases, but can also be formed by using raw materials having a silicon source, a carbon source, and a nitrogen source and adjusting the amount of carbon to be introduced. The amount of carbon to be introduced can be adjusted by using carbon sources different in carbon content, in addition to the flow rate adjustment described above. Note that a carbon source may also serve as a silicon source or a nitrogen source. For example, trimethylsilane described above doubles as a carbon source and a silicon source. If an organic amine is used, the organic amine can double as a carbon source and a nitrogen source.

The thinner an insulating film as a support structure is, the more the reduction in the area of a lower electrode outer wall surface which is used as a capacitive portion can be curbed, but the more a crack is likely to appear at the time of wet etching. The thickness of first silicon nitride film 63 for first and fourth insulating films (63a and 63b) at the time of formation is, but not particularly limited to, preferably 70 nm or less, more preferably 60 nm or less. The thickness of the first silicon nitride film is preferably 30 nm or more, more preferably 40 nm or more. The thickness of the first silicon nitride film left after wet etching is preferably at least 20 nm.

As shown in FIGS. 13A and 13B, conductor film (titanium nitride film) 68 to serve as a lower electrode of a capacitor is formed to a thickness of about 10 nm by CVD.

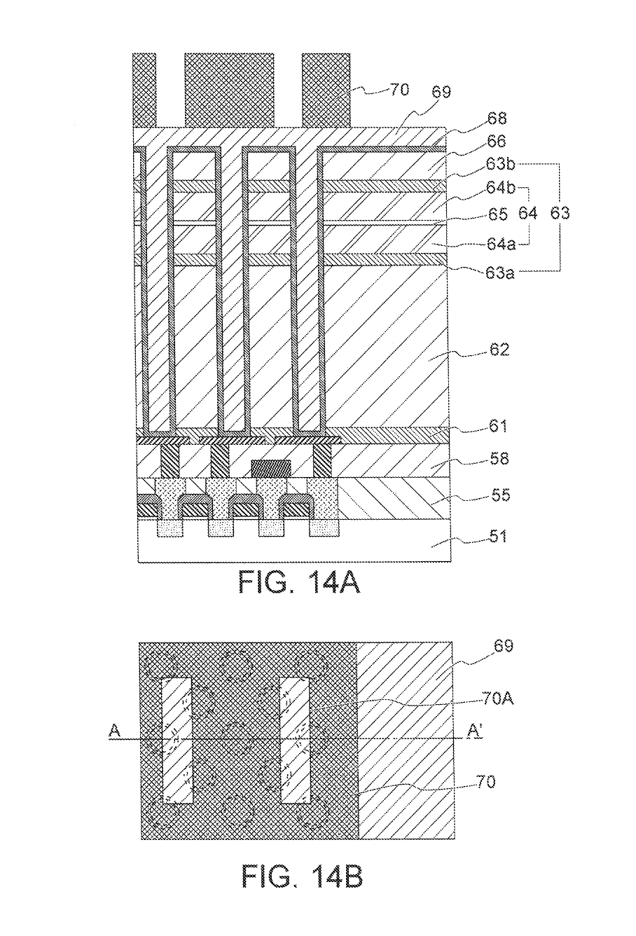

As shown in FIGS. 14A and 14B, a silicon oxide film is formed as protective film 69 to a thickness of 20 nm, and an antireflection film and photoresist 70 are applied to protective film 69 by spin coating. Slit patterns 70A having an opening width of 40 nm are formed in the photoresist by lithography. Although the silicon oxide film as protective film 69 is shown to reach the bottoms of the lower electrodes (titanium nitride film 68) in this example, the silicon oxide film may be formed by a film formation method with poor coverage such that only upper portions of the lower electrodes are clogged. Slit patterns 70A are formed in the shape of a rectangle elongated in a Y direction (first direction) which is a direction in which the boundary between a memory cell region and a peripheral circuit region extends. One slit pattern 70A is formed such that multiple lower electrodes circular in a plan view are arranged so as to partially overlap with two long sides of slit pattern 70A. FIG. 14B shows an example in which two slit patterns 70A are formed such that the centers in a longitudinal direction of two slit patterns 70A lie on a straight line in an X direction (second direction) perpendicular to the Y direction. The present invention, however, is not limited to this, and slit patterns 70A may be formed in a staggered arrangement such that the centers in the longitudinal direction are shifted relative to each other in the Y direction. The lengths of the long sides of slit patterns 70A may be different. Alternatively, multiple slit patterns 70A may be in the shape of a rectangle elongated in the X direction. Alternatively, multiple slit patterns 70A may be in the shape of a rectangle elongated in a third direction diagonal to the Y direction and X direction.

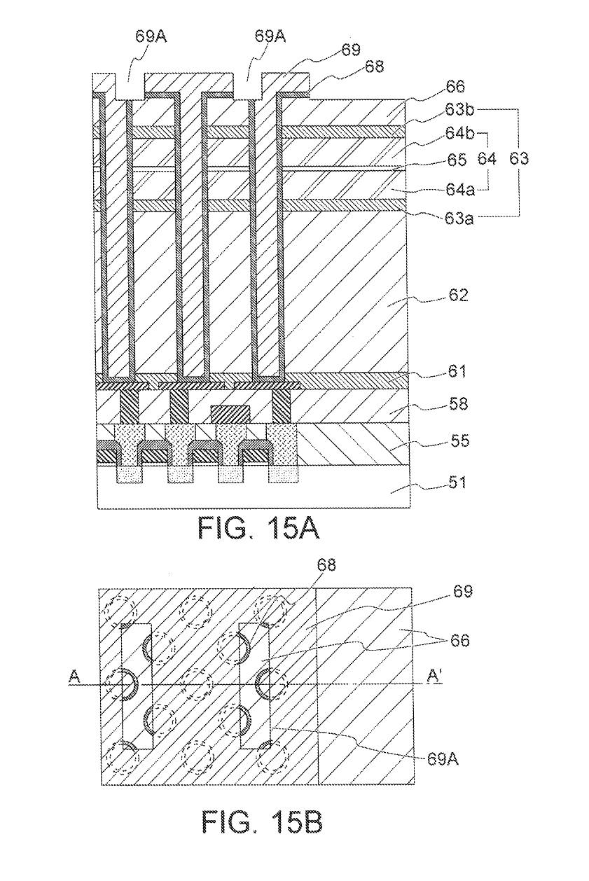

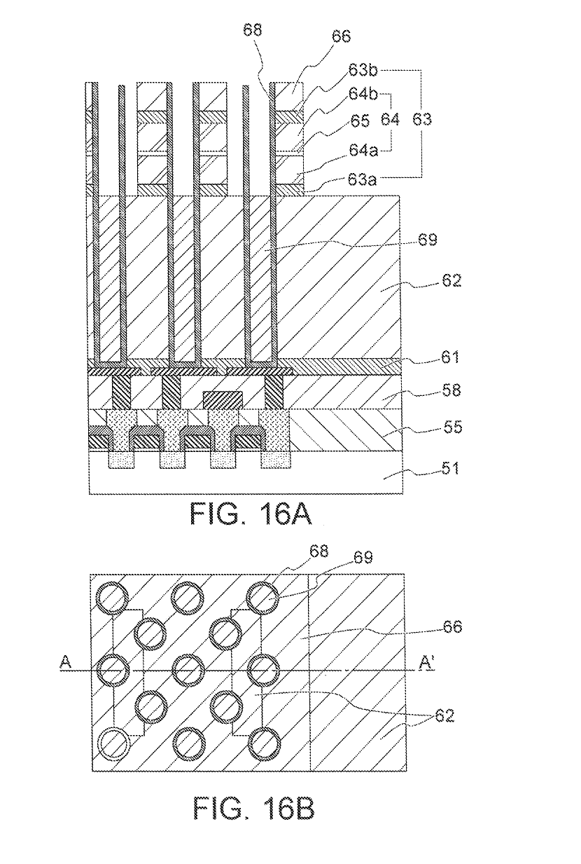

As shown in FIGS. 15A and 15B, protective film 69 and conductor film 68 are etched by dry etching using photoresist 70 as a mask to form openings 69A. As shown in FIGS. 16A and 16B, the silicon oxide films (66 and 65), the first silicon nitride films (63b and 63a), and the second silicon nitride films (64b and 64a) are sequentially etched by dry etching using conductor film 68 as a mask to expose underlying mold insulating film 62. With this process, slit patterns 69A are formed to extend through insulating films 66 to 63a in order from the top.

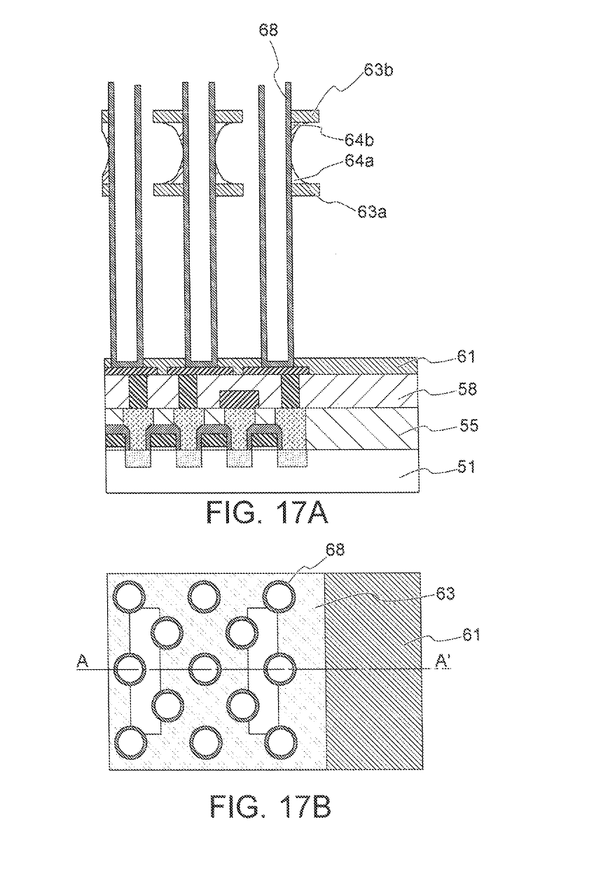

As shown in FIGS. 17A and 17B, mold insulating film 62 is removed by wet etching using hydrofluoric acid (HF). At this time, the silicon oxide films (66, 65, 62, and 69) are first etched, and the second silicon nitride films (64a and 64b) are then etched. This process leaves support structures of the respective first silicon nitride films (63a and 63b) at an upper portion and a middle portion of each lower electrode of the capacitor. Since the first silicon nitride film formed as stopper film 61 is also left, an etching solution can be prevented from penetrating into the underlying interlayer insulating films. Additionally, since third insulating film 65 is formed so as to be sandwiched between the second silicon nitride films (64a and 64b), the second silicon nitride films (64a and 64b) are also etched from surfaces exposed after removal of third insulating film 65. This allows efficient removal of the second silicon nitride films (64a and 64b). FIG. 17A shows a state in which the second silicon nitride films (64a and 64b) are being etched and removed.

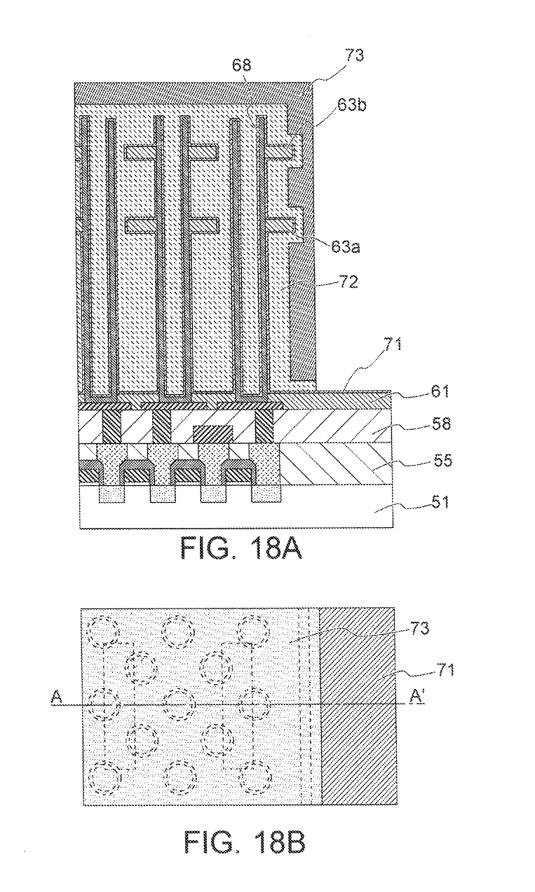

After that, as shown in FIGS. 18A and 18B, capacitor dielectric film 71 and upper electrode 72 are formed by CVD, and plate electrode 73 is further formed by CVD using a metal film of, e.g., tungsten. Note that upper electrode 72 need not be a single-layered film and that doped polysilicon or a B-doped SiGe film is preferably applied to a titanium nitride film to fill in gaps and reduce unevenness. After that, an interlayer insulating film covering plate electrode 73, upper-layer wiring connected to plate electrode 73, and the like are formed, thereby completing the memory cell region. Wiring of the peripheral circuit region and the like are formed around the memory cell region, thereby completing a semiconductor device.

As described above, according to the present embodiment, when silicon oxide films are removed, thick silicon nitride films are left. The thicknesses of the silicon nitride films are reduced in a stepwise manner. Accordingly, even if the thickness of each lower electrode is small, a phenomenon in which the lower electrode is twisted by a support structure can be prevented. Additionally, support films can be formed at two locations, an upper portion and a middle portion of each lower electrode, by using the relatively thin first silicon nitride films (63a and 63b), and a reduction in the area of a lower electrode outer wall used as a capacitive portion of the lower electrode can be curbed. Moreover, formation of support films at two or more locations allows a further reduction in the thickness of each lower electrode and avoidance of torsion of a lower electrode having low mechanical strength that occurs locally due to manufacturing variation.

### Modified Embodiment

In the above-described second embodiment, the support films (the first silicon nitride films) as support structures are respectively formed at two locations, an upper portion and a middle portion. The present invention, however, is not limited to this, and the support films can be formed at three or more locations, i.e., three or more first silicon nitride films can be formed. Note that since the area of a lower electrode outer wall decreases with an increase in the number of support locations, the first silicon nitride films to be left as a support structure need to be made thinner.

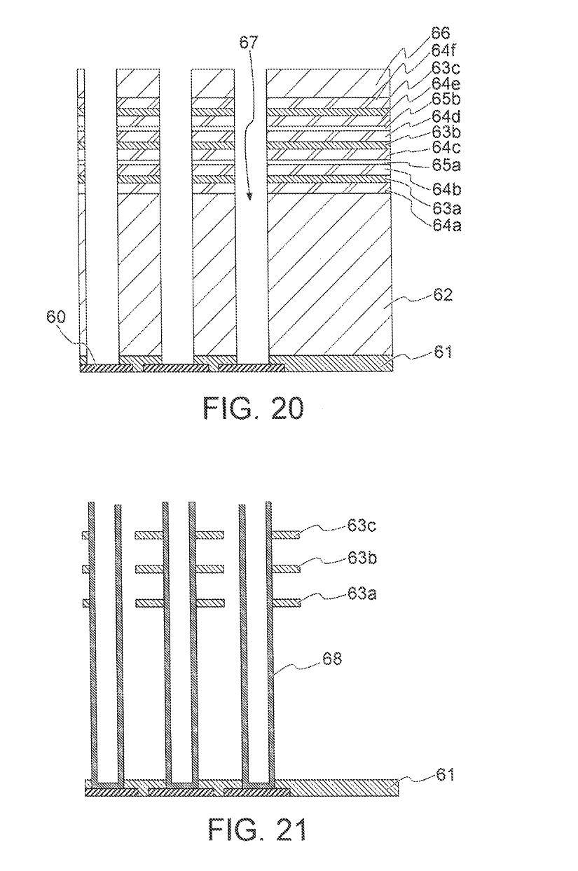

FIGS. 20 and 21 are step cross-sectional views for explaining a method of manufacturing a semiconductor device according to the present modification. FIG. 20 shows a state in which storage node holes 67 are formed, like FIG. 12. FIG. 21 shows a state after wet etching. Note that a structure underneath stopper film 61 is not shown in these figures.

As shown in FIG. 20, in the present modification, second silicon nitride film 64a having a thickness of 50 nm, first silicon nitride film 63a having a thickness of 30 nm, second silicon nitride film 64b having a thickness of 50 nm, silicon oxide film 65a having a thickness of 20 nm, second silicon nitride film 64c having a thickness of 50 nm, first silicon nitride film 63b having a thickness of 30 nm, second silicon nitride film 64d having a thickness of 50 nm, silicon oxide film 65b having a thickness of 20 nm, second silicon nitride film 64e having a thickness of 50 nm, first silicon nitride film 63c having a thickness of 30 nm, and second silicon nitride film 64f having a thickness of 50 nm are first formed on mold insulating film 62. Silicon oxide film 66 is formed on second silicon nitride film 64f to a thickness of 100 nm.

After that, like the second embodiment, conductor film 68 to serve as lower electrodes is formed, and the silicon oxide films and second nitride films are removed, as shown in FIG. 21. With this process, structures which support each lower electrode at three locations in a height direction can be formed.

As described above, since the second silicon nitride films are formed on upper and lower surfaces, respectively, of each first silicon nitride film, the first silicon nitride film is mainly exposed to etching from a side surface at the time of wet etching and is exposed to etching from the upper and lower surfaces for a short period of time. As a result, even if the thickness of each first silicon nitride film is thin, an amount by which the thickness is reduced is small, and a thickness required for a support structure is ensured even after wet etching. The three-point support structure can more effectively prevent an electrode twist and can curb reduction in the area of a lower electrode outer wall even if the number of support locations increases.

The structure in which the second silicon nitride films are formed on the upper and lower surfaces, respectively, of each first silicon nitride film can also be applied to a two-point support structure as in the second embodiment.

The embodiment and modification described above have illustrated examples in which third insulating film (silicon oxide film) 65 is sandwiched between second silicon nitride films 64. If the ratio of the etch rate of first silicon nitride film 63 to that of second silicon nitride film 64 is sufficiently low, single-layered second silicon nitride film 64 may be used without inserting third insulating film 65 between two second silicon nitride films 64. From the point of view of reducing the time to etch the second silicon nitride film and an amount by which the first silicon nitride film is etched, it is more preferable to insert third insulating film 65 having an etch rate higher than that of the second silicon nitride film between the second silicon nitride films as two separate layers.

Stopper film 61 is made of the first silicon nitride film. Although stopper film 61 only needs to be a film having a wet etch rate lower than that of the second silicon nitride film such that stopper film 61 can prevent an etching solution from penetrating into an underlying layer while the second silicon nitride films are etched and removed, stopper film 61 preferably has a wet etch rate equal to or lower than that of the first silicon nitride film in order to function also as a bottom holding member which supports the capacitor lower electrodes at the bottoms.

Overlying silicon oxide film 66 may be omitted. In the above second embodiment, first and second silicon nitride films 63 and 64 are etched using conductor film 68 on silicon oxide film 66 as a mask to form openings. The openings can be formed by dry-etching first silicon nitride films 63 and second silicon nitride films 64 using a photomask after removing conductor film 68 on insulating film 66 in advance by etching back. If conductor film 68 is divided into individual capacitor lower electrodes in advance by etching back, protective film 69 is formed in order to inhibit portions of conductor film 68 on the inner walls and at the bottoms of storage node holes 67 from being exposed to etching. An organic coating (e.g., a resist) can be used in addition to a silicon oxide film.

In FIGS. 12A to 18C described in the second embodiment, a planar transistor is taken as an example of a transistor constituting a memory cell of a semiconductor device. The present invention, however, is not limited to this, and use of a transistor with a recessed gate structure, a transistor with a buried gate structure, or a vertical transistor is advantageous in miniaturization. Use of capacitor contact pads is not essential, and capacitor contact plugs and lower electrodes may be connected.

A support structure according to the present invention is also applicable to a compensation capacitance lower electrode that is formed in the same shape as a capacitor lower electrode of a memory cell.

The present invention also includes embodiments as described below:

A. A method of manufacturing a semiconductor device, the method including:

forming a mold insulating film and a support film including a first insulating material having a stress in a range from +700 MPa to −700 MPa on a substrate with a capacitor contact plug formed at the substrate;

forming a hole extending from the support film to reach the capacitor contact plug;

forming a conductor film in the form of a closed-end cylinder in the hole; and

removing the mold insulating film to expose an outer wall of the conductor film.

B. The method of manufacturing a semiconductor device according to A, wherein the mold insulating film is mainly composed of silicon oxide, and the removing the mold insulating film is subjected by using a chemical solution containing hydrofluoric acid.
C. The method of manufacturing a semiconductor device according to B, wherein the first insulating material has an etch rate of 1 nm/sec or less relative to the chemical solution containing hydrofluoric acid.
D. The method of manufacturing a semiconductor device according to A, wherein the first insulating material is silicon carbon nitride.
E. A method of manufacturing a semiconductor device, the method including:

forming a support film on an interlayer insulating film;

forming a hole extending through the support film and the interlayer insulating film;

forming an inner wall film in the hole; and

removing the interlayer insulating film such that the support film is left to form the inner wall film so as to be supported by the support film,

wherein the support film is made of an insulating film containing silicon carbon nitride.

F. The method of manufacturing a semiconductor device according to E, wherein the inner wall film is a conductor film constituting a capacitor.
G. A method of manufacturing a semiconductor device, the method including:

forming a mold insulating film to a predetermined thickness on a substrate and then forming a layered structure in which at least a first insulating film, a second insulating film, and the first insulating film are stacked;

forming multiple holes extending through the layered structure and the mold insulating film by dry etching;

forming a conductor film on a bottom surface and a side wall of each of the holes;

forming an opening extending through the layered structure by dry etching to expose the mold insulating film; and

removing the mold insulating film via the opening by wet etching,

wherein the second insulating film has a wet etch rate higher than a wet etch rate of the first insulating film and lower than a wet etch rate of the mold insulating film in the wet etching, and the second insulating film is also removed by the wet etching to form support structures for the conductor film that are composed of the respective first insulating films.

H. The method of manufacturing a semiconductor device according to G, wherein the second insulating film has two separate layers, between which a third insulating film having a wet etch rate higher than the wet etch rate of the second insulating film is sandwiched.
I. The method of manufacturing a semiconductor device according to G, wherein the respective second insulating films are formed in contact with upper and lower surfaces of each of the first insulating films.
J. The method of manufacturing a semiconductor device according to H, wherein the mold insulating film and the third insulating film comprise silicon oxide, and the first insulating film and the second insulating film comprise silicon nitride.
K. The method of manufacturing a semiconductor device according to J, wherein the wet etching is performed using hydrofluoric acid, and the wet etch rate of the first insulating film is not more than three-quarters of the wet etch rate of the second insulating film.
L. The method of manufacturing a semiconductor device according to J, wherein the first insulating film is formed as a silicon carbon nitride film that is obtained by doping silicon nitride with carbon, and the second insulating film is formed as a silicon carbon nitride film more lightly doped with carbon than the first insulating film or a silicon nitride film undoped with carbon.
M. The method of manufacturing a semiconductor device according to L, wherein the first and second insulating films are each formed by using a raw material including a silicon source, a carbon source, and a nitrogen source and adjusting the amount of carbon to be introduced.
N. The method of manufacturing a semiconductor device according to M, wherein the first and second insulating films are each formed by plasma CVD using silane as the silicon source, trymethylsilane as the carbon source, and ammonia as the nitrogen source while a flow rate of trymethylsilane is adjusted.
O. The method of manufacturing a semiconductor device according to N, wherein dry etch rates of the first insulating film and the second insulating film are substantially the same.
P. The method of manufacturing a semiconductor device according to G, wherein the substrate includes a stopper film having a wet etch rate lower than the wet etch rate of the second insulating film at a surface in contact with the mold insulating film.
Q. The method of manufacturing a semiconductor device according to P, wherein the substrate includes a transistor formed on a semiconductor substrate, an interlayer insulating film covering the transistor, and a contact plug extending through the interlayer insulating film and connected to one of source/drain diffusion layers of the transistor, each hole is formed at a part where the hold is electrically connectable to the contact plug, and the conductor film is formed so as to be electrically connected to the contact plug.
R. The method of manufacturing a semiconductor device according to Q, wherein each of the conductor films serves as a lower electrode of a capacitor, and the method further includes:

forming capacitor dielectric films on an inner wall and an outer wall of each of the exposed lower electrodes after the wet etching; and

forming an upper electrode on the capacitor dielectric films.

S. The method of manufacturing a semiconductor device according to G, the method further including:

forming a fourth insulating film having a wet etch rate higher than the wet etch rate of the second insulating film on the layered structure,

wherein each hole is formed so as to extend from the fourth insulating film through the mold insulating film underneath the layered structure, a protective film is formed in the hole so as to clog at least an upper end of the hole after the conductor film is also formed on the fourth insulating film, and the layered structure is dry-etched using the conductor film as a mask after a pattern of the opening is transferred to the conductor film.

T. The method of manufacturing a semiconductor device according to G, wherein the opening is formed to expose a part of an outer wall of each of the conductor films at the sidewall of the hole.

What is claimed is:

1. A semiconductor device comprising:
a capacitor;
a first support film and a second support film separately supporting the capacitor in a height direction thereof, each of the first and the second support films comprising silicon nitride doped with carbon; and
a first slit pattern in the first support film and a second slit pattern in the second support film, the first and the second support patterns being laterally aligned to each other, wherein
the capacitor includes a lower electrode formed in a cylindrical hole penetrating the first and the second support films, the lower electrode having a substantially flat sidewall extending at least through the first and the second support film.

2. The semiconductor device according to claim 1, wherein at least one of the first and second support films comprises a first insulating material having a stress within a range of +700 MPa to −700 MPa.

3. The semiconductor device according to claim 2, wherein the first insulating material has an etch rate relative to hydrofluoric acid of 1 nm/sec or less.

4. The semiconductor device according to claim 1, wherein the capacitor includes a capacitor dielectric film formed on inner and outer walls of the lower electrode, and an upper electrode formed on the capacitor dielectric film, and at least one of the first and second support films is in contact with the outer wall of the lower electrode.

5. The semiconductor device according to claim 4, wherein the semiconductor device comprises a memory cell region in which a plurality of the capacitors is arranged in an array and a peripheral circuit region that is arranged around the memory cell region, and at least one of the first and second support films covers a whole of the memory cell region.

6. The semiconductor device according to claim 5, wherein at least one of the first and second support films has openings near the peripheral circuit region.

7. The semiconductor device according to claim 5, wherein the lower electrode comprises a first titanium nitride film and the upper electrode comprises a second titanium nitride film in contact with the capacitor dielectric film and a gap filling material selected from doped polysilicon and boron-doped silicon germanium to fill gaps in the memory cell region.

8. The semiconductor device according to claim 5, wherein the memory cell region comprises:
a transistor formed on a semiconductor substrate;
an interlayer insulating film covering the transistor; and
a contact plug extending through the interlayer insulating film, being connected to one of source/drain diffusion layers of the transistor and being electrically connected to the capacitor.

9. The semiconductor device according to claim 5, wherein the semiconductor device further comprises a bottom-holding member that includes an insulating material around a bottom of the lower electrode of each of the capacitors.

10. The semiconductor device according to claim 9, wherein the insulating material that constitutes the bottom-holding member comprises silicon nitride doped with carbon.

11. The semiconductor device according to claim 1, wherein a thickness of the lower electrode is 10 nm or less.

12. The semiconductor device according to claim 1, wherein a thickness of each of the first and second support films is within a range of 20 nm to 70 nm.

13. The semiconductor device according to claim 4, wherein the at least one of the first and second support films is in contact with the outer wall of the lower electrode at a portion above a middle height of the lower electrode.
